(19) United States
(12) Patent Application Publication
(10) Pub. No.: US 2010/0033458 A1
(43) Pub. Date: Feb. 11, 2010

(54) Buffer circuit having voltage switching function, and liquid crystal display device

(75) Inventors: Shinsaku Shimizu, Jiangsu Province (CN); Kazuhiro Maeda, Kyoto (JP); Ichiro Shiraki, Mie (JP)

Correspondence Address: HARNESS, DICKEY & PIERCE, P.L.C., P.O. BOX 8910, RESTON, VA, 20195, US

(73) Assignee: SHARP KABUSHIKI KAISHA, OSAKA-SHI (JP)

(21) Appl. No.: 12/311,978

(22) PCT Filed: Jul. 5, 2007
(86) PCT No.: PCT/JP2007/063423

§ 371 Date: Apr. 21, 2009

(30) Foreign Application Priority Data
Nov. 7, 2006 (JP) 2006-301630

(51) Int. Cl. G09G 5/00; H03K 17/00

(52) U.S. Cl. 345/211; 327/365; 345/90

(57) ABSTRACT

In one embodiment of the invention, a capacitor is provided between a node and a negative-side input terminal of a differential amplifier. A switch SW11 is provided between the negative-side input terminal and an output terminal of the differential amplifier. A switch SW12 is provided between the node and the output terminal of the differential amplifier. Switches SW13 to SW16 are provided for switching between a voltage of the node and a positive-side input voltage of the differential amplifier. The switches SW11 and SW12 are on during different periods. In a positive polarity mode, the switches SW13 and SW16 are when the switch SW11 is on while the switch SW16 is on when the switch SW12 is on. In a negative polarity mode, the switches SW14 and SW15 are on when the switch SW11 is on while the switch SW16 is on when the switch SW12 is on. Thus, two types of gradation voltages each required for AC drive of a liquid crystal can be generated with a small circuit scale.

### TECHNICAL FIELD

The present invention relates to a buffer circuit having a function of switching a level of an output voltage, and a liquid crystal display device including the same.

### BACKGROUND ART

In order to prevent deterioration of a liquid crystal, conventionally, a liquid crystal display device switches a polarity of a voltage to be applied to the liquid crystal, that is, performs AC drive. Examples of the AC drive include frame inversion drive, line inversion drive, dot inversion drive and the like. In order to perform the AC drive, the liquid crystal display device keeps a voltage to be applied to a common electrode (hereinafter, referred to as a common electrode voltage) at a certain level or switches the common electrode voltage between a high level and a low level. In any case, the liquid crystal display device must generate a gradation voltage which is higher than the common electrode voltage by a predetermined amount (an amount according to a video signal level) and a gradation voltage which is lower than the common electrode voltage by the predetermined amount.

FIG. 16 is a circuit diagram showing a gradation voltage generation circuit in a conventional liquid crystal display device. The circuit shown in FIG. 16 includes a plurality of resistors connected in series and a plurality of transistors 91 to 94, and generates 64 gradation voltages in a range between a minimum voltage VL and a maximum voltage VH. The circuit shown in FIG. 16 receives a control signal POL and a control signal POLB (an inverted signal of the control signal POL) each indicating a polarity of the gradation voltage. When the control signal POL is at a HIGH level, the transistors 91 and 94 are on. Herein, the gradation voltage to be outputted from a terminal close to a node Na becomes high while the gradation voltage to be outputted from a terminal distant from the node Na becomes low. When the control signal POL is at a LOW level, the transistors 92 and 93 are on. Herein, the gradation voltage to be outputted from the terminal close to the node Na becomes low while the gradation voltage to be outputted from the terminal distant from the node Na becomes high. The circuit shown in FIG. 16 can selectively generate two types of gradation voltages each required for AC drive of a liquid crystal.

Moreover, Patent Document 1 discloses a gradation voltage generation circuit shown in FIG. 17. The circuit shown in FIG. 17 includes a voltage generation circuit 95 for each gradation. The voltage generation circuit 95 outputs one of an addition output (VN+Vs) and a subtraction output (VN−Vs) in accordance with an AC modulation control signal M. The circuit shown in FIG. 17 can also selectively generate two types of gradation voltages each required for AC drive of a liquid crystal.
[Patent Document 1] Japanese Laid-Open Patent Publication No. 6-34943

### DISCLOSURE OF THE INVENTION

### Problems to be Solved by the Invention

However, a liquid crystal display device including one of the foregoing gradation voltage generation circuits has the following problems. In the case of using the circuit shown in FIG. 16, there is a difference in temperature characteristic between the transistor and the resistor. Consequently, the gradation voltage varies due to a change in temperature. Moreover, the transistor desirably has a resistance value which is almost equal to zero. Therefore, the transistor must be satisfactorily increased in size, resulting in disadvantageous increase in circuit scale and power consumption. In the case of using the circuit shown in FIG. 17, on the other hand, the voltage generation circuit 95, which includes an addition circuit, a subtraction circuit and a switch, must be provided for each gradation, resulting in disadvantageous increase in circuit scale.

Hence, an object of the present invention is to provide a buffer circuit capable of accurately generating two types of gradation voltages each required for AC drive of a liquid crystal with a small circuit scale, and a liquid crystal display device including the same.

### Means for Solving the Problems

A first aspect of the present invention provides a buffer circuit for switching a level of an output voltage in accordance with an operation mode, including: a differential amplifier; a capacitor having a first terminal, and a second terminal connected to a negative-side input terminal of the differential amplifier; a first switch switching connection/disconnection between the negative-side input terminal and an output terminal of the differential amplifier; a second switch switching connection/disconnection between the first terminal and the output terminal of the differential amplifier; a first voltage switch unit selecting one of a data voltage and a reference voltage to apply the selected voltage to the first terminal; and a second voltage switch unit selecting one of the data voltage and the reference voltage to apply the selected voltage to a positive-side input terminal of the differential amplifier.

A second aspect of the present invention provides the buffer circuit according to the first aspect of the present invention, wherein the first and second switches are on during different periods, respectively, in the first operation mode, the first voltage switch unit selects the data voltage in the state that the first switch is on while the second voltage switch unit selects the reference voltage, and in the second operation mode, the first voltage switch unit selects the reference voltage in the state that the first switch is on while the second voltage switch unit selects the data voltage in the state that the first switch is on and selects the reference voltage in the state that the second switch is on.

A third aspect of the present invention provides the buffer circuit according to the first aspect of the present invention, wherein the first voltage switch unit includes: a third switch having a first end to which the data voltage is applied, and a second end connected to the first terminal; and a fourth switch having a first end to which the reference voltage is applied, and a second end connected to the first terminal, and the second voltage switch unit includes: a fifth switch having a first end to which the data voltage is applied, and a second end connected to the positive-side input terminal of the differential amplifier; and a sixth switch having a first end to which the reference voltage is applied, and a second end connected to the positive-side input terminal of the differential amplifier.

A fourth aspect of the present invention provides a buffer circuit for switching a level of an output voltage in accordance with an operation mode, including: a differential amplifier having a positive-side input terminal to which a reference voltage is applied; a first capacitor having a first terminal, and a second terminal connected to a negative-side input terminal of the differential amplifier; a second capacitor having a third terminal, and a fourth terminal connected to the negative-side input terminal of the differential amplifier; a first switch switching connection/disconnection between the negative-side input terminal and an output terminal of the differential amplifier; a second switch switching connection/disconnection between the third terminal and the output terminal of the differential amplifier; a third switch switching application/non-application of the reference voltage to the third terminal; and a voltage switch unit selecting one of a data voltage and the reference voltage to apply the selected voltage to the first terminal.

A fifth aspect of the present invention provides the buffer circuit according to the fourth aspect of the present invention, wherein the first and second switches are on during different periods, respectively, the third switch is on during a period which is substantially equal to the ON period of the first switch, in the first operation mode, the voltage switch unit selects the data voltage in the state that the first switch is on and selects the reference voltage in the state that the second switch is on, and in the second operation mode, the voltage switch unit selects the reference voltage in the state that the first switch is on and selects the data voltage in the state that the second switch is on.

A sixth aspect of the present invention provides the buffer circuit according to the fourth aspect of the present invention, wherein the voltage switch unit includes: a fourth switch having a first end to which the data voltage is applied, and a second end connected to the first terminal; and a fifth switch having a first end to which the reference voltage is applied, and a second end connected to the first terminal.

A seventh aspect of the present invention provides the buffer circuit according to the fourth aspect of the present invention, further including: a third capacitor having a fifth terminal, and a sixth terminal connected to the negative-side input terminal of the differential amplifier; and an auxiliary voltage switch unit selecting one of the data voltage and the reference voltage to apply the selected voltage to the fifth terminal.

An eighth aspect of the present invention provides the buffer circuit according to the seventh aspect of the present invention, wherein the auxiliary voltage switch unit selects the data voltage in a state that the first switch is on and selects the reference voltage in a state that the second switch is on.

A ninth aspect of the present invention provides the buffer circuit according to the seventh aspect of the present invention, wherein the auxiliary voltage switch unit selects the reference voltage in a state that the first switch is on and selects the data voltage in a state that the second switch is on.

A tenth aspect of the present invention provides the buffer circuit according to the seventh aspect of the present invention, wherein the auxiliary voltage switch unit includes: a sixth switch having a first end to which the data voltage is applied, and a second end connected to the fifth terminal; and a seventh switch having a first end to which the reference voltage is applied, and a second end connected to the fifth terminal.

An eleventh aspect of the present invention provides a liquid crystal display device including the buffer circuit according to any one of the first to tenth aspect of the present invention.

### EFFECTS OF THE INVENTION

According to the first aspect of the present invention, each of the first and second voltage switch units can switch a level of an output voltage in accordance with an operation mode. Upon reception of an appropriate reference voltage, accordingly, two types of gradation voltages each required for AC drive of a liquid crystal can be generated. Moreover, the output voltage of the buffer circuit does not depend on an offset voltage of the differential amplifier. Therefore, a liquid crystal display device including this buffer circuit can be reduced in circuit scale of a gradation voltage generation circuit and a D/A converter. Accordingly, two types of gradation voltages each required for AC drive of a liquid crystal can be accurately generated with a small circuit scale.

According to the second aspect of the present invention, the output voltage equates to (Vr+ΔV) in the first operation mode and equates to (Vr−ΔV) in the second operation mode, where Vr represents the reference voltage and ΔV represents a difference between the data voltage and the reference voltage. In the first operation mode, as described above, a voltage which is higher than the reference voltage by a predetermined amount can be generated. In the second operation mode, a voltage which is lower than the reference voltage by the predetermined amount can be generated. Thus, two types of gradation voltages each required for AC drive of a liquid crystal can be generated selectively.

According to the third aspect of the present invention, each of the first voltage switch unit that selects one of the data voltage and the reference voltage to apply the selected voltage to the first terminal and the second voltage switch unit that selects one of the data voltage and the reference voltage to apply the selected voltage to the positive-side input terminal of the differential amplifier can be readily configured with two switches.

According to the fourth aspect of the present invention, the voltage switch unit can switch a level of an output voltage in accordance with an operation mode. Upon reception of an appropriate reference voltage, accordingly, two types of gradation voltages each required for AC drive of a liquid crystal can be generated. Moreover, the output voltage of the buffer circuit does not depend on an offset voltage of the differential amplifier. Therefore, a liquid crystal display device including this buffer circuit can be reduced in circuit scale of a gradation voltage generation circuit and a D/A converter. Accordingly, two types of gradation voltages each required for AC drive of a liquid crystal can be accurately generated with a small circuit scale. In addition, the output voltage can be made larger in amplitude than the data voltage, and a differential amplifier having a narrow input voltage range can be used.

According to the fifth aspect of the present invention, the output voltage equates to {Vr+(Ca/Cb)×ΔV} in the first operation mode and equates to {Vr−(Ca/Cb)×ΔV} in the second operation mode, where Vr represents the reference voltage, ΔV represents a difference between the data voltage and the reference voltage, and Ca and Cb represent capacitances of the first and second capacitors, respectively. In the first operation mode, as described above, a voltage which is higher than the reference voltage by a predetermined amount can be generated. In the second operation mode, a voltage which is lower than the reference voltage by the predetermined amount can be generated. Thus, two types of gradation voltages each required for AC drive of a liquid crystal can be selectively generated. Further, the output voltage can be made larger in amplitude than the data voltage.

According to the sixth aspect of the present invention, the voltage switch unit that selects one of the data voltage and the reference voltage to apply the selected voltage to the first terminal can be readily configured with two switches.

According to the seventh aspect of the present invention, when switching a level of an output voltage in accordance with an operation mode, the auxiliary voltage switch unit can correct the level of the output voltage.

According to the eighth aspect of the present invention, provision of the third capacitor having a capacitance Cc allows the output voltage to be increased by (Cc/Cb)×ΔV in each of the first operation mode and the second operation mode. Accordingly, the reference voltage can be corrected in accordance with the data voltage. Then, a voltage which is higher than the corrected reference voltage by a predetermined amount can be generated in the first operation mode and a voltage which is lower than the corrected reference voltage by the predetermined amount can be generated in the second operation mode. Thus, two types of gradation voltages each required for AC drive of a liquid crystal can be accurately generated.

According to the ninth aspect of the present invention, provision of the third capacitor having the capacitance Cc allows the output voltage to be decreased by (Cc/Cb)×ΔV in each of the first operation mode and the second operation mode. Accordingly, the reference voltage can be corrected in accordance with the data voltage. Then, a voltage which is higher than the corrected reference voltage by a predetermined amount can be generated in the first operation mode and a voltage which is lower than the corrected reference voltage by the predetermined amount can be generated in the second operation mode. Thus, two types of gradation voltages each required for AC drive of a liquid crystal can be accurately generated.

According to the tenth aspect of the present invention, the auxiliary voltage switch unit that selects one of the data voltage and the reference voltage to apply the selected voltage to the fifth terminal can be readily configured with two switches.

According to the eleventh aspect of the present invention, a liquid crystal display device which can accurately generate two types of gradation voltages each required for AC drive of a liquid crystal with a small circuit scale can be obtained.

### BRIEF DESCRIPTION OF THE DRAWINGS

FIG. 1 is a circuit diagram showing a buffer circuit according to a first embodiment of the present invention.

FIG. 2 is a timing chart showing a change in state of each switch of the buffer circuit shown in FIG. 1 in a positive polarity mode.

FIG. 3 is a timing chart showing a change in state of each switch of the buffer circuit shown in FIG. 1 in a negative polarity mode.

FIG. 4 is a block diagram showing a first configuration example of a liquid crystal display device including the buffer circuit shown in FIG. 1.

FIG. 5 is a block diagram showing a second configuration example of a liquid crystal display device including the buffer circuit shown in FIG. 1.

FIG. 6 is a diagram showing main components in a third configuration example of a liquid crystal display device including the buffer circuit shown in FIG. 1.

FIG. 7A is a diagram showing a gradation voltage and a common electrode voltage in a case where each of the liquid crystal display devices shown in FIGS. 4 to 6 performs opposite DC drive.

FIG. 7B is a diagram showing a gradation voltage and a common electrode voltage in a case where each of the liquid crystal display devices shown in FIGS. 4 to 6 performs opposite AC drive.

FIG. 8 is a circuit diagram showing a buffer circuit according to a second embodiment of the present invention.

FIG. 9 is a timing chart showing a change in state of each switch of the buffer circuit shown in FIG. 8 in a positive polarity mode.

FIG. 10 is a timing chart showing a change in state of each switch of the buffer circuit shown in FIG. 8 in a negative polarity mode.

FIG. 11 is a circuit diagram showing a buffer circuit according to a third embodiment of the present invention.

FIG. 12 is a timing chart showing a first change in state of each switch of the buffer circuit shown in FIG. 11 in a positive polarity mode.

FIG. 13 is a timing chart showing a first change in state of each switch of the buffer circuit shown in FIG. 11 in a negative polarity mode.

FIG. 14 is a timing chart showing a second change in state of each switch of the buffer circuit shown in FIG. 11 in the positive polarity mode.

FIG. 15 is a timing chart showing a second change in state of each switch of the buffer circuit shown in FIG. 11 in the negative polarity mode.

FIG. 16 is a circuit diagram showing a gradation voltage generation circuit in a conventional liquid crystal display device.

FIG. 17 is a circuit diagram showing a gradation voltage generation circuit in a conventional liquid crystal display device.

### DESCRIPTION OF REFERENCE SYMBOLS

1, 2, 3 buffer circuit

10, 20, 30 differential amplifier

11, 21, 22, 31, 32, 33 capacitor

SW11 to SW16, SW21 to SW25, SW31 to SW37 switch

19, 29, 39 switch control circuit

### BEST MODE FOR CARRYING OUT THE INVENTION

### First Embodiment

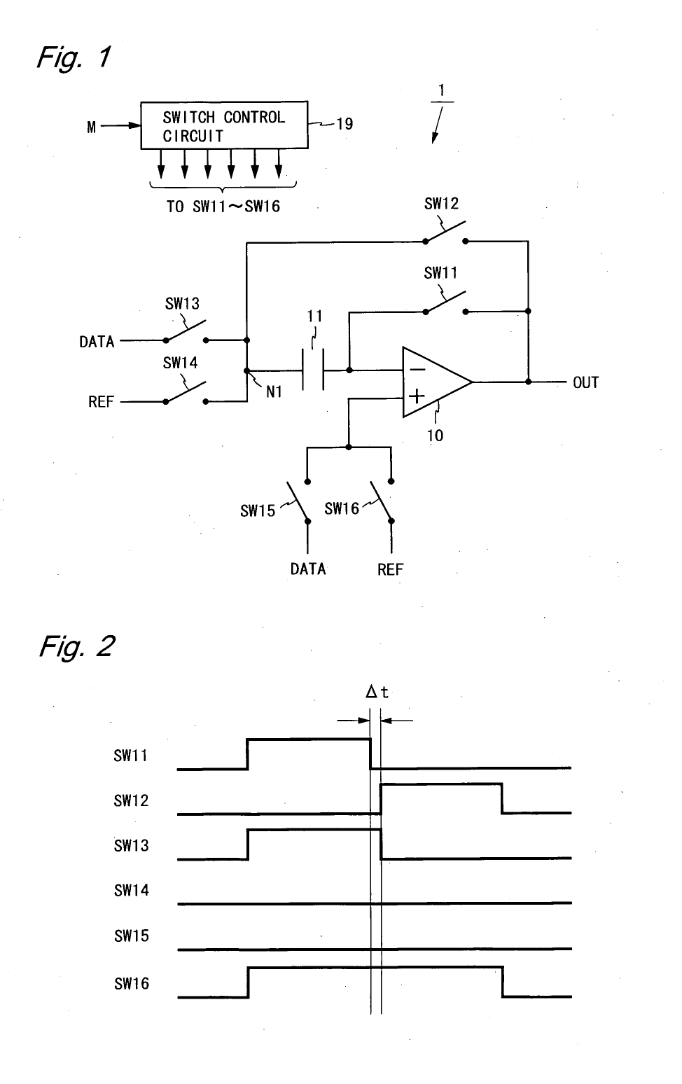

FIG. 1 is a circuit diagram showing a buffer circuit according to a first embodiment of the present invention. The buffer circuit 1 shown in FIG. 1 outputs an output signal OUT, based on a data signal DATA, a reference signal REF and a mode selection signal M. The buffer circuit 1 has a function of switching a voltage level of the output signal OUT in accordance with the mode selection signal M, and is used for generating two types of gradation voltages each required for AC drive of a liquid crystal, and other purposes. Hereinafter, a voltage of the data signal DATA is referred to as a data voltage Vd and a voltage of the reference signal REF is referred to as a reference voltage Vr.

As shown in FIG. 1, the buffer circuit 1 includes a differential amplifier 10, a capacitor 11, switches SW11 to SW16, and a switch control circuit 19. The capacitor 11 has a first terminal connected to a negative-side input terminal of the differential amplifier 10, and a second terminal connected to a node N1. The differential amplifier 10 outputs a signal corresponding to the output signal OUT of the buffer circuit 1. The switch SW11 is provided between the negative-side input terminal and an output terminal of the differential amplifier 10 to switch connection/disconnection between the negative-side input terminal and the output terminal of the differential amplifier 10. The switch SW12 is provided between the node N1 and the output terminal of the differential amplifier 10 to switch connection/disconnection between the node N1 and the output terminal of the differential amplifier 10.

The switch SW13 has a first end receiving the data signal DATA and a second end connected to the node N1. The switch SW14 has a first end receiving the reference signal REF and a second end connected to the node N1. The switch SW15 has a first end receiving the data signal DATA and a second end connected to a positive-side input terminal of the differential amplifier 10. The switch SW16 has a first end receiving the reference signal REF and a second end connected to the positive-side input terminal of the differential amplifier 10. The switches SW13 and SW14 serve as a first voltage switch unit that selects one of the data voltage Vd and the reference voltage Vr to apply the selected voltage to the node N1. The switches SW15 and SW16 serve as a second voltage switch unit that selects one of the data voltage Vd and the reference voltage Vr to apply the selected voltage to the positive-side input terminal of the differential amplifier 10.

The buffer circuit 1 operates in two operation modes (hereinafter, referred to as a positive polarity mode and a negative polarity mode). The mode selection signal M is a control signal for switching the operation mode of the buffer circuit 1. When outputting switch control signals to the switches SW11 to SW16, the switch control circuit 19 switches the manner in which the switch control signals vary, in accordance with the mode selection signal M.

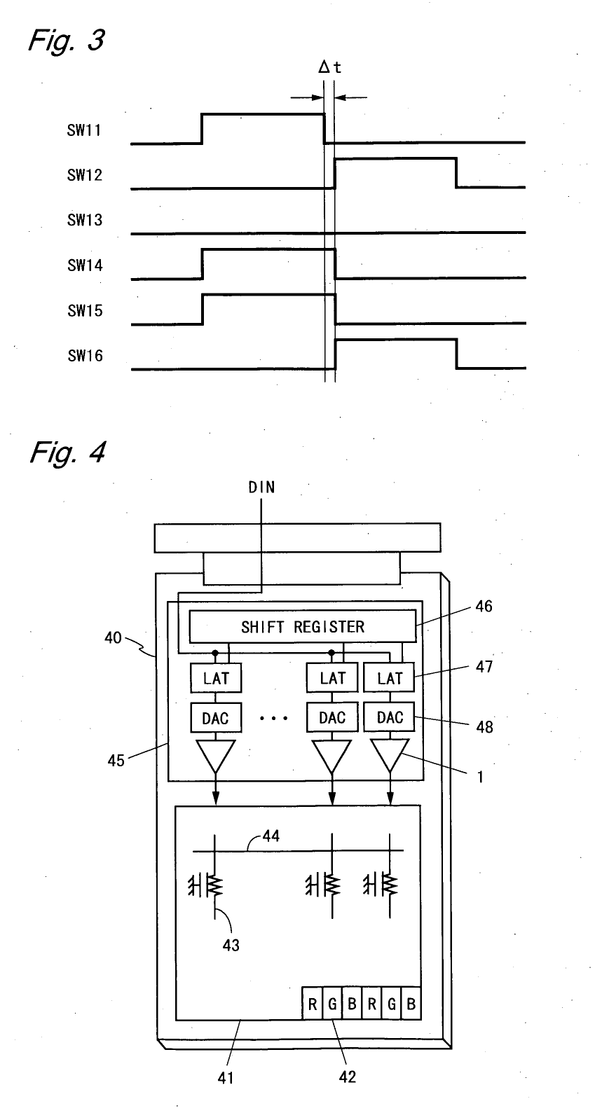

FIG. 2 is a timing chart showing a change in state of each switch in the positive polarity mode, and FIG. 3 is a timing chart showing a change in state of each switch in the negative polarity mode. In the drawings each showing the changes in state of the respective switches, hereinafter, a HIGH level denotes an ON state (a conductive state) and a LOW level denotes an OFF state (a nonconductive state).

As shown in FIGS. 2 and 3, the switches SW11 and SW12 are on alternately during different periods in the buffer circuit 1. Therefore, a period during which the switch SW11 is on (hereinafter, referred to as a preparation period) and a period during which the switch SW12 is on (hereinafter, referred to as an output period) appear alternately. During the preparation period, the buffer circuit 1 executes a process for compensating an offset voltage of the differential amplifier 10. During the output period, the buffer circuit 1 outputs a voltage in accordance with the data voltage Vd. It is preferable herein that an allowance time Δt is provided between the preparation period and the output period. That is, it is preferable that the switch SW11 turns off and, after a lapse of the allowance time Δt, the switch SW12 turns on.

Hereinafter, description will be given of operations of the buffer circuit 1. In the following description, A (A>>1) represents an amplification factor of the differential amplifier 10, Vo represents an offset voltage of the differential amplifier 10, Ca represents a capacitance of the capacitor 11, V1 represents a voltage of the output signal OUT in the preparation period, and V2 represents a voltage of the output signal OUT in the output period.

With reference to FIG. 2, first, description will be given of the operations in the positive polarity mode. During the preparation period, the switches SW11, SW13 and SW16 are on while the remaining switches are off. Herein, a positive-side input voltage of the differential amplifier 10 is set at Vr and each of a negative-side input voltage and an output voltage of the differential amplifier 10 is set at V1. Therefore, the following equation (1a) is established. Moreover, the following equation (1b) is derived from the relation A>>1.

V1=A(Vr−V1+Vo) (1a)

V1=Vr+Vo (1b)

Moreover, the data voltage Vd is applied to the node N1; therefore, an inter-electrode voltage of the capacitor 11 is given by an equation V1−Vd=Vr+Vo−Vd. Herein, the capacitor 11 accumulates electric charges in an amount which is “Ca” times as large as the applied voltage.

During the output period, the switches SW12 and SW16 are on while the remaining switches are off. Herein, the positive-side input voltage of the differential amplifier 10 is set at Vr and the output voltage of the differential amplifier 10 is set at V2. Moreover, the voltage V2 is applied to the node N1, and the inter-electrode voltage of the capacitor 11 does not vary from (Vr+Vo−Vd). Therefore, the negative-side input voltage of the differential amplifier 10 equates to {V2+(Vr+Vo−Vd)}. Accordingly, the following equation (1c) is established. Moreover, the following equation (1d) is derived from the relation A>>1.

V2=A[Vr−{V2+(Vr+Vo−Vd)}+Vo] (1c)

V2=Vd (1d)

With reference to FIG. 3, next, description will be given of the operations in the negative polarity mode. During the preparation period, the switches SW11, SW14 and SW15 are on while the remaining switches are off. Herein, the positive-side input voltage of the differential amplifier 10 is set at Vd and each of the negative-side input voltage and the output voltage of the differential amplifier 10 is set at V1. Therefore, the following equation (2a) is established. Moreover, the following equation (2b) is derived from the relation A>>1.

V1=A(Vd−V1+Vo) (2a)

V1=Vd+Vo (2b)

Moreover, the reference voltage Vr is applied to the node N1; therefore, the inter-electrode voltage of the capacitor 11 is given by an equation V1−Vr=Vd+Vo−Vr. Herein, the capacitor 11 accumulates electric charges in an amount which is “Ca” times as large as the applied voltage.

During the output period, the switches SW12 and SW16 are on while the remaining switches are off. Herein, the positive-side input voltage of the differential amplifier 10 is set at Vr and the output voltage of the differential amplifier 10 is set at V2. Moreover, the voltage V2 is applied to the node N1, and the inter-electrode voltage of the capacitor 11 does not vary from (Vd+Vo−Vr). Therefore, the negative-side input voltage of the differential amplifier 10 equates to {V2+(Vd+Vo−Vr)}. Accordingly, the following equation (2c) is established. Moreover, the following equation (2d) is derived from the relation A>>1.

V2=A[Vr−{V2+(Vd+Vo−Vr)}+Vo] (2c)

V2=2Vr−Vd (2d)

It is assumed herein that (Vd−Vr) in each of the equations (1d) and (2d) is ΔV. In this case, the voltage of the output signal OUT is expressed by the following equation (1) in the positive polarity mode, and is expressed by the following equation (2) in the negative polarity mode.

V2=Vr+ΔV (1)

V2=Vr−ΔV (2)

As described above, the buffer circuit 1 outputs a voltage which is higher than the reference voltage Vr by ΔV in the positive polarity mode, and outputs a voltage which is lower than the reference voltage Vr by ΔV in the negative polarity mode. Moreover, each of the output voltages does not depend on the offset voltage Vo of the differential amplifier 10.

Next, description will be given of a liquid crystal display device including the buffer circuit 1. FIG. 4 is a block diagram showing a first configuration example of a liquid crystal display device including the buffer circuit 1. In the liquid crystal display device shown in FIG. 4, a pixel array 41, a data signal line drive circuit 45 and a scanning signal line drive circuit (not shown) are integrally formed on a liquid crystal panel 40. The pixel array 41 includes a plurality of pixel circuits 42 arranged in a two dimensional form, a plurality of data signal lines 43, and a plurality of scanning signal lines 44. Each data signal line 43 is connected to the corresponding pixel circuits 42 arranged in a single column, and each scanning signal line 44 is connected to the corresponding pixel circuits 42 arranged in a single row.

The scanning signal line drive circuit selectively activates the scanning signal lines 44 in succession to select the pixel circuits 42 on one row in succession. The data signal line drive circuit 45 includes a shift register 46, a plurality of latches 47, a plurality of D/A converters 48 and a plurality of buffer circuits 1. Moreover, the data signal line drive circuit 45 performs line sequential drive to drive the data signal lines 43 in succession, based on a digital video signal DIN. More specifically, the data signal line drive circuit 45 receives digital video signals DIN in synchronization with timing control signals. Herein, the latch 47 accumulates the digital video signals DIN in succession. After completion of supply of the digital video signals DIN corresponding to one row, the D/A converter 48 converts into an analog signal the digital video signal DIN accumulated in the latch 47 to generate an analog data signal DATA. The buffer circuit 1 amplifies the data signal DATA output from the D/A converter 48, and drives the data signal line 43 using the amplified data signal.

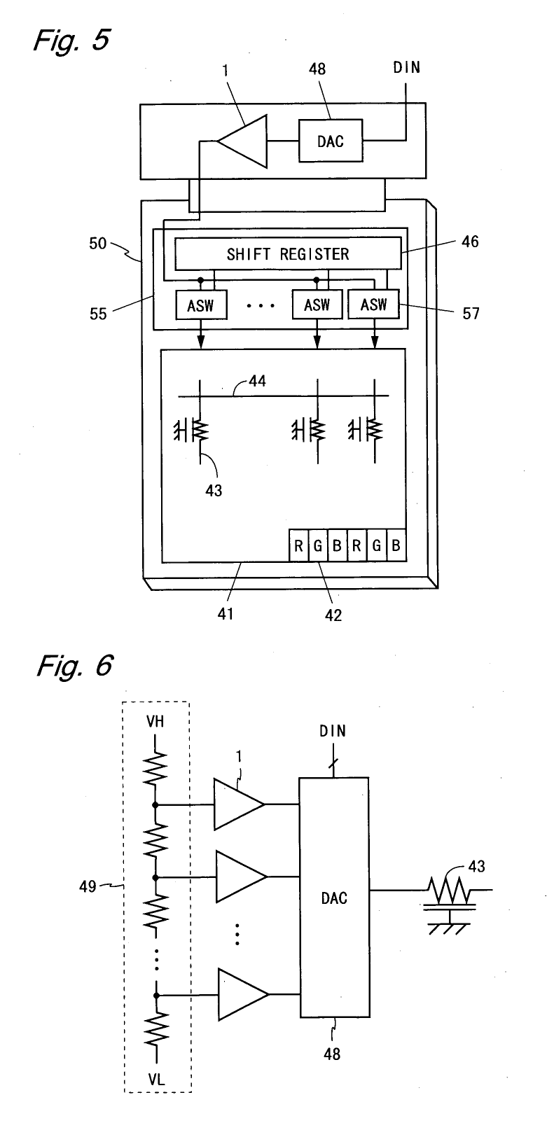

FIG. 5 is a block diagram showing a second configuration example of a liquid crystal display device including the buffer circuit 1. In the liquid crystal display device shown in FIG. 5, a pixel array 41, a shift register 46 and analog switches 57 forming a portion 55 of a data signal line drive circuit, and a scanning signal line drive circuit (not shown) are integrally formed on a liquid crystal panel 50. A D/A converter 48 and the buffer circuit 1 forming the remaining portion of the data signal line drive circuit are provided outside the liquid crystal panel 50. In this manner, the buffer circuit 1 may be provided outside the liquid crystal panel 50.

In each of the liquid crystal display devices shown in FIGS. 4 and 5, the buffer circuit 1 is provided subsequent to the D/A converter 48. As shown in FIG. 6, alternatively, the buffer circuit 1 may be provided subsequent to a resistance division circuit 49 that generates a plurality of gradation voltages and prior to the D/A converter 48. In this case, the buffer circuit 1 receives, as the data signals DATA, output signals (each having a voltage corresponding to a gradation) of the resistance division circuit 49. The output signal of the buffer circuit 1 is used when the D/A converter 48 performs D/A conversion.

Each of the liquid crystal display devices shown in FIGS. 4 to 6 performs AC drive such as frame inversion drive, line inversion drive or dot inversion drive. In addition, the liquid crystal display device performs drive to keep a common electrode voltage at a certain level (hereinafter, referred to as opposite DC drive) or drive to switch the common electrode voltage between a high level and a low level (hereinafter, referred to as opposite AC drive). In each of the liquid crystal display devices shown in FIGS. 4 to 6, the buffer circuit 1 generates two types of gradation voltages (i.e., a gradation voltage which is higher than the common electrode voltage by a predetermined amount and a gradation voltage which is lower than the common electrode voltage by the predetermined amount) each required for AC drive of a liquid crystal.

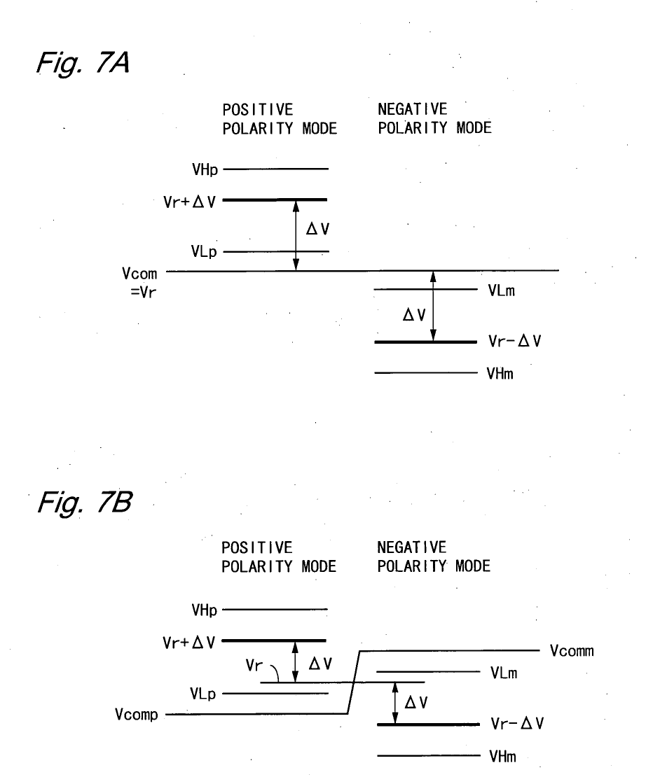

FIG. 7A is a diagram showing a gradation voltage and a common electrode voltage in the case where each of the liquid crystal display devices shown in FIGS. 4 to 6 performs the opposite DC drive. FIG. 7B is a diagram showing a gradation voltage and a common electrode voltage in the case where each of the liquid crystal display devices shown in FIGS. 4 to 6 performs the opposite AC drive. In FIGS. 7A and 7B, VHp represents a voltage corresponding to a maximum gradation in the positive polarity mode, VLp represents a voltage corresponding to a minimum gradation in the positive polarity mode, VHm represents a voltage corresponding to a maximum gradation in the negative polarity mode, VLm represents a voltage corresponding to a minimum gradation in the negative polarity mode, Vcom represents a common electrode voltage, Vcomp represents a common electrode voltage in the positive polarity mode, and Vcomm represents a common electrode voltage in the negative polarity mode. In FIG. 7A, there is established a relation VHm<VLm<Vcom<VLp<VMp. In FIG. 7B, there are established relations VHm<VLm<Vcomm, Vcomp<VLp<VMp, and Vcomp<Vcomm.

In the liquid crystal display device that performs either the opposite DC drive or the opposite AC drive, the buffer circuit 1 receives, as the data signal DATA, the output signal of the D/A converter 48 (or the output signal of the resistance division circuit 49). However, it is assumed herein that the voltage of the output signal is higher than the common electrode voltage. Moreover, the buffer circuit 1 also receives a mode selection signal M in accordance with a type of AC drive. In a case where the liquid crystal display device shown in FIG. 4 performs line sequential drive, for example, all the buffer circuits 1 receive mode selection signals M each inverted every one line time.

In the liquid crystal display device that performs the opposite DC drive (FIG. 7A), the buffer circuit 1 receives, as the reference voltage Vr, the common electrode voltage Vcom (or a voltage obtained by addition of a pull-in voltage to the common electrode voltage Vcom). In the liquid crystal display device that performs the opposite AC drive (FIG. 7B), the buffer circuit 1 receives, as the reference voltage Vr, a mean value of two types of common electrode voltages (Vcomp+Vcomm)/2 (or a voltage obtained by addition of a pull-in voltage to the mean value). In FIGS. 7A and 7B, the pull-in voltage is set at zero.

As expressed by the equations (1) and (2), the buffer circuit 1 outputs the voltage which is higher than the reference voltage Vr by ΔV in the positive polarity mode, and outputs the voltage which is lower than the reference voltage Vr by ΔV in the negative polarity mode. In the liquid crystal display device that performs the opposite DC drive, accordingly, when the reference voltage Vr is made equal to the common electrode voltage Vcom, the buffer circuit 1 can selectively generate a gradation voltage which is higher than the common electrode voltage Vcom by a predetermined amount and a gradation voltage which is lower than the common electrode voltage Vcom by the predetermined amount (see FIG. 7A). In the liquid crystal display device that performs the opposite AC drive, on the other hand, when the reference voltage Vr is made equal to the mean value of the two types of common electrode voltages (Vcomp+Vcomm)/2, the buffer circuit 1 can selectively generate a gradation voltage which is higher than the common electrode voltage Vcomp in the positive polarity mode by the predetermined amount and a gradation voltage which is lower than the common electrode voltage Vcomm in the negative polarity mode by the predetermined amount (see FIG. 7B). In each of the liquid crystal display devices shown in FIGS. 4 to 6, as described above, the buffer circuit 1 can generate two types of gradation voltages each required for AC drive of a liquid crystal.

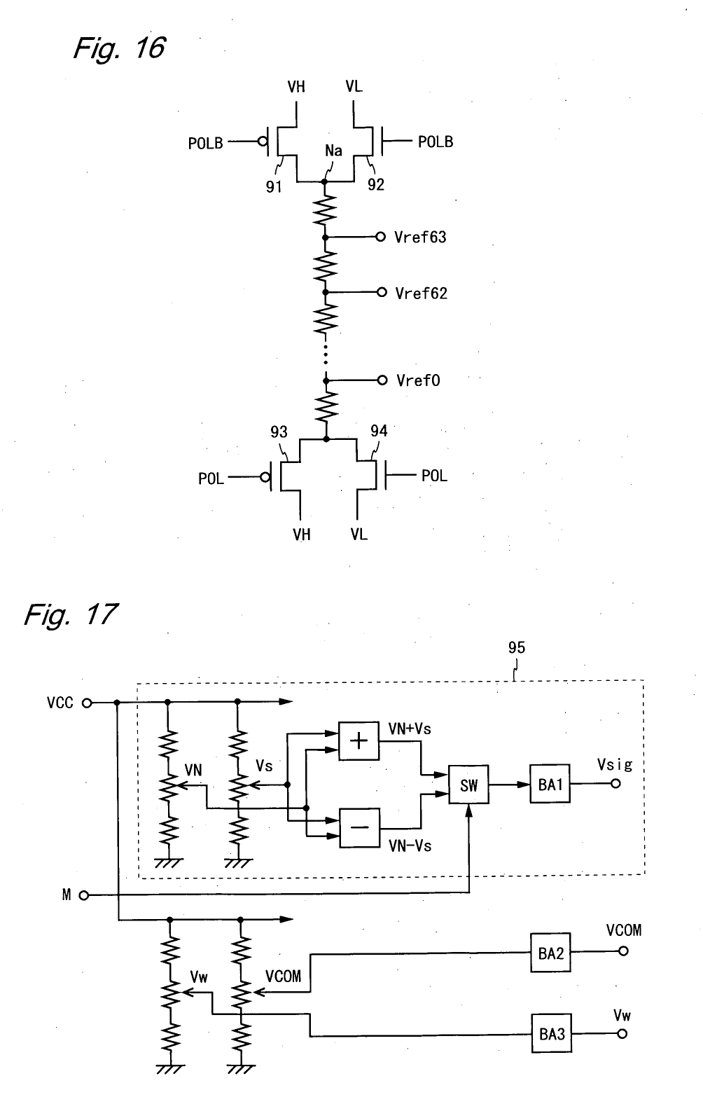

In a conventional liquid crystal display device, a circuit other than a buffer circuit (e.g., the gradation voltage generation circuits shown in FIGS. 16 and 17) generates two types of gradation voltages each required for AC drive of a liquid crystal. The buffer circuit receives the gradation voltage from the circuit, and then outputs the gradation voltage without changing a voltage level of the gradation voltage. Consequently, the conventional liquid crystal display device has the following problems. That is, the gradation voltage generation circuit and the D/A converter are disadvantageously increased in circuit scale. Moreover, the gradation voltage disadvantageously varies due to a change in temperature.

In the liquid crystal display device according to this embodiment, on the other hand, the buffer circuit 1 generates two types of gradation voltages each required for AC drive of a liquid crystal. Accordingly, circuit scale of the gradation voltage generation circuit and the D/A converter can be reduced, as compared with the conventional liquid crystal display device. Moreover, the output voltage of the buffer circuit 1 does not depend on the offset voltage of the differential amplifier 10. Accordingly, the gradation voltage can be accurately generated irrespective of the offset voltage of the differential amplifier 10.

As described above, according to the buffer circuit 1 according to this embodiment and the liquid crystal display device including the same, two types of gradation voltages each required for AC drive of a liquid crystal can be accurately generated with a small circuit scale.

### Second Embodiment

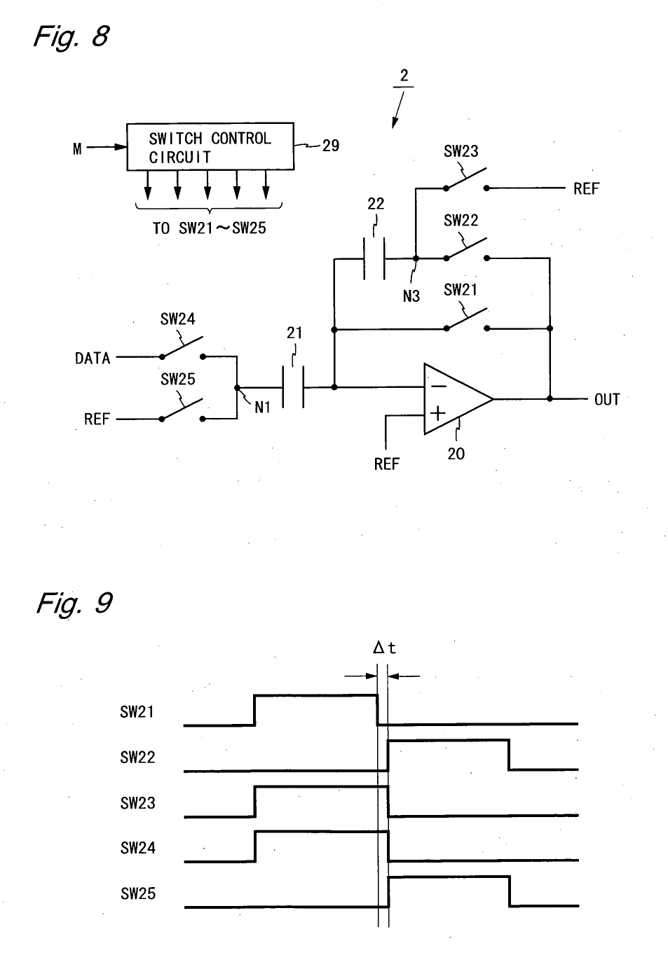

FIG. 8 is a circuit diagram showing a buffer circuit according to a second embodiment of the present invention. The buffer circuit 2 shown in FIG. 8 includes a differential amplifier 20, capacitors 21 and 22, switches SW21 to SW25, and a switch control circuit 29. As in the case of the buffer circuit 1 according to the first embodiment, the buffer circuit 2 is used for generating two types of gradation voltages each required for AC drive of a liquid crystal in each of the liquid crystal display devices shown in FIGS. 4 to 6, and other purposes.

As shown in FIG. 8, the differential amplifier 20 has a positive-side input terminal receiving a reference signal REF, and a negative-side input terminal connected to one of first terminals of the capacitors 21 and 22. Second terminals of the capacitors 21 and 22 are connected to nodes N1 and N3, respectively.

The switch SW21 is provided between the negative-side input terminal and an output terminal of the differential amplifier 20 to switch connection/disconnection between the negative-side input terminal and the output terminal of the differential amplifier 20. The switch SW22 is provided between the node N3 and the output terminal of the differential amplifier 20 to switch connection/disconnection between the node N3 and the output terminal of the differential amplifier 20. The switch SW23 has a first end receiving the reference signal REF and a second end connected to the node N3. The switch SW23 switches application/non-application of the reference voltage Vr to the node N3.

The switch SW24 has a first end receiving a data signal DATA and a second end connected to the node N1. The switch SW25 has a first end receiving the reference signal REF and a second end connected to the node N1. The switches SW24 and SW25 serve as a voltage switch unit that selects one of a data voltage Vd and a reference voltage Vr to apply the selected voltage to the node N1.

As in the case of the buffer circuit 1 according to the first embodiment, the buffer circuit 2 operates in a positive polarity mode and a negative polarity mode. When outputting switch control signals to the switches SW21 to SW25, the switch control circuit 29 switches the manner in which the switch control signals vary, in accordance with a mode selection signal M.

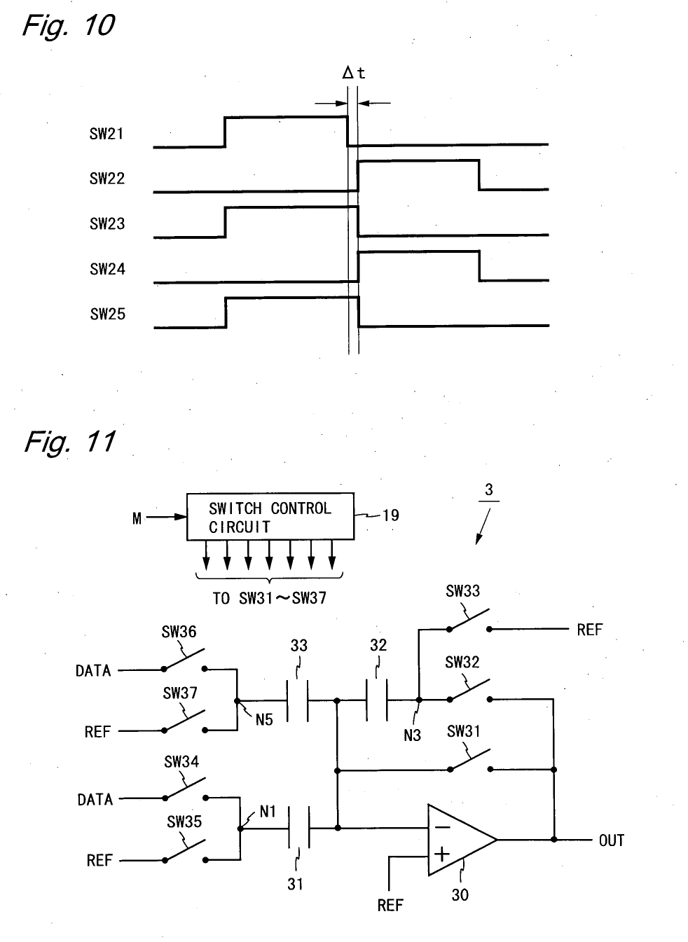

FIG. 9 is a timing chart showing a change in state of each switch in the positive polarity mode, and FIG. 10 is a timing chart showing a change in state of each switch in the negative polarity mode. In the buffer circuit 2, as shown in FIGS. 9 and 10, the switches SW21 and SW22 are on alternately during different periods, and the switches SW23 is on during a period which is almost equal to the ON period of the switch SW21. Moreover, a preparation period during which the switch SW21 is on and an output period during which the switch SW22 is on appear alternately. Also in the buffer circuit 2, it is preferable that an allowance time At is provided between the preparation period and the output period.

Hereinafter, description will be given of operations of the buffer circuit 2. In the following description, A (A>>1) represents an amplification factor of the differential amplifier 20, Vo represents an offset voltage of the differential amplifier 20, Ca and Cb represent capacitances of the capacitors 21 and 22, respectively, V1 represents a voltage of an output signal OUT in the preparation period, and V2 represents a voltage of the output signal OUT in the output period.

With reference to FIG. 9, first, description will be given of the operations in the positive polarity mode. During the preparation period, the switches SW21, SW23 and SW24 are on while the remaining switches are off. Herein, a positive-side input voltage of the differential amplifier 20 is set at Vr and each of a negative-side input voltage and an output voltage of the differential amplifier 20 is set at V1. Therefore, the following equation (3a) is established. Moreover, the following equation (3b) is derived from the relation A>>1.

V1=A(Vr−V1+Vo) (3a)

V1=Vr+Vo (3b)

Moreover, the data voltage Vd is applied to the node N1; therefore, an inter-electrode voltage of the capacitor 21 is given by an equation V1−Vd=Vr+Vo−Vd. Herein, the capacitor 21 accumulates electric charges in an amount which is “Ca” times as large as the applied voltage. On the other hand, the reference voltage Vr is applied to the node N3; therefore, an inter-electrode voltage of the capacitor 22 is given by an equation V1−Vr=Vo. Herein, the capacitor 22 accumulates electric charges in an amount which is “Cb” times as large as the applied voltage.

During the output period, the switches SW22 and SW25 are on while the remaining switches are off. Herein, the positive-side input voltage of the differential amplifier 20 is set at Vr and the output voltage of the differential amplifier 20 is set at V2. Therefore, when the negative-side input voltage of the differential amplifier 20 is set at V3, the following equation (3c) is established. Moreover, the following equation (3d) is derived from the relation A>>1.

V2=A(Vr−V3+Vo) (3c)

V3=Vr+Vo (3d)

Moreover, the inter-electrode voltage of the capacitor 21 equates to (V3−Vr), and the inter-electrode voltage of the capacitor 22 equates to (V3−V2).

A total amount of electric charges accumulated in the capacitors 21 and 22 does not vary between the preparation period and the output period. Therefore, the following equation (3e) is established.

Ca(Vr+Vo−Vd)+Cb·Vo=Ca(V3−Vr)+Cb(V3−V2) (3e)

The following equation (3f) is derived from the equations (3d) and (3e).

V2=Vr+(Ca/Cb)×(Vd−Vr) (3f)

With reference to FIG. 10, next, description will be given of the operations in the negative polarity mode. During the preparation period, the switches SW21, SW23 and SW25 are on while the remaining switches are off. Herein, the positive-side input voltage of the differential amplifier 20 is set at Vr and each of the negative-side input voltage and the output voltage of the differential amplifier 20 is set at V1. Therefore, the equations (3a) and (3b) are established also in the negative polarity mode. Moreover, the reference voltage Vr is applied to each of the nodes N1 and N3; therefore, each of the inter-electrode voltage of the capacitor 21 and the inter-electrode voltage of the capacitor 22 is given by an equation V1−Vr=Vo. Herein, the capacitor 21 accumulates electric charges in an amount which is “Ca” times as large as the applied voltage while the capacitor 22 accumulates electric charges in an amount which is “Cb” times as large as the applied voltage.

During the output period, the switches SW22 and SW24 are on while the remaining switches are off. Herein, the positive-side input voltage of the differential amplifier 20 is set at Vr and the output voltage of the differential amplifier 20 is set at V2. Therefore, when the negative-side input voltage of the differential amplifier 20 is set at V3, the equations (3c) and (3d) are established also in the negative polarity mode. Moreover, the inter-electrode voltage of the capacitor 21 equates to (V3−Vd), and the inter-electrode voltage of the capacitor 22 equates to (V3−V2).

A total amount of electric charges accumulated in the capacitors 21 and 22 does not vary between the preparation 10 period and the output period. Therefore, the following equation (4e) is established.

Ca·Vo+Cb·Vo=Ca(V3−Vd)+Cb(V3−V2) (4e)

The following equation (4f) is derived from the equations (3d) and (4e).

V2=Vr−(Ca/Cb)×(Vd−Vr) (4f)

It is assumed herein that (Vd−Vr) in each of the equations (3f) and (4f) is ΔV. In this case, the voltage of the output signal OUT is expressed by the following equation (3) in the positive polarity mode, and is expressed by the following equation (4) in the negative polarity mode.

V2=Vr+(Ca/Cb)×ΔV (3)

V2=Vr−(Ca/Cb)×ΔV (4)

As described above, the buffer circuit 2 outputs a voltage which is higher than the reference voltage Vr by (Ca/Cb)×ΔV in the positive polarity mode, and outputs a voltage which is lower than the reference voltage Vr by (Ca/Cb)×ΔV in the negative polarity mode. Moreover, each of the output voltages does not depend on the offset voltage Vo of the differential amplifier 20.

As in the case of the buffer circuit 1 according to the first embodiment, accordingly, according to the buffer circuit 2 according to the second embodiment, two types of gradation voltages each required for AC drive of a liquid crystal can be accurately generated with a small circuit scale. Moreover, the output voltage of the buffer circuit 2 varies in an amount which is “(Ca/Cb)” times as large as a degree of change of the data voltage Vd. Accordingly, an amplitude of the output voltage can be made larger than that of the data voltage Vd through use of the capacitors 21 and 22 each having an appropriate capacitance. Moreover, the positive-side input voltage of the differential amplifier 20 is fixed at the reference voltage Vr. Therefore, the differential amplifier 20 having a narrow input voltage range can be used.

### Third Embodiment

FIG. 11 is a circuit diagram showing a buffer circuit according to a third embodiment of the present invention. The buffer circuit 3 shown in FIG. 11 includes a differential amplifier 30, capacitors 31 to 33, switches SW31 to SW37, and a switch control circuit 39. As in the case of the buffer circuit 1 according to the first embodiment, the buffer circuit 3 is used for generating two types of gradation voltages each required for AC drive of a liquid crystal, and other purposes.

As shown in FIG. 11, the differential amplifier 30 has a positive-side input terminal receiving a reference signal REF, and a negative-side input terminal connected to first terminals of the capacitors 31 to 33. Second terminals of the capacitors 31 to 33 are connected to nodes N1, N3 and N5, respectively.

The switches SW31 to SW35 are equal in connection form and function to the switches SW21 to SW25 according to the second embodiment. The switch SW36 has a first end receiving a data signal DATA and a second end connected to the node N5. The switch SW37 has a first end receiving the reference signal REF and a second end connected to the node N5. The switches SW36 and SW37 serve as an auxiliary voltage switch unit that selects one of a data voltage Vd and a reference voltage Vr to apply the selected voltage to the node N5.

As in the case of the buffer circuit 1 according to the first embodiment, the buffer circuit 3 operates in a positive polarity mode and a negative polarity mode. When outputting switch control signals to the switches SW31 to SW37, the switch control circuit 39 switches the manner in which the switch control signals vary, in accordance with a mode selection signal M.

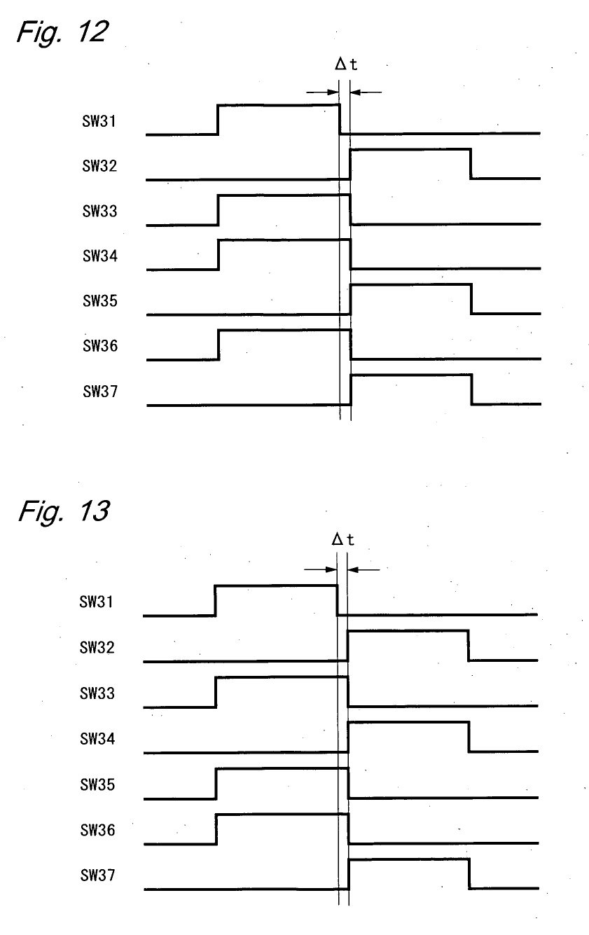

FIG. 12 is a timing chart showing a first change in state of each switch in the positive polarity mode, and FIG. 13 is a timing chart showing a second change in state of each switch in the negative polarity mode. In the buffer circuit 3, as shown in FIGS. 12 and 13, the switches SW31 and SW32 are on alternately during different periods, the switches SW33 and SW36 are on during a period which is almost equal to the ON period of the switch SW31, and the switch SW37 is on during a period which is equal to the ON period of the switch SW32. Moreover, a preparation period during which the switch SW31 is on and an output period during which the switch SW32 is on appear alternately. Also in the buffer circuit 3, it is preferable that an allowance time At is provided between the preparation period and the output period.

Hereinafter, description will be given of operations of the buffer circuit 3. In the following description, A (A>>1) represents an amplification factor of the differential amplifier 30, Vo represents an offset voltage of the differential amplifier 30, Ca, Cb and Cc represent capacitances of the capacitors 31, 32 and 33, respectively, V1 represents a voltage of an output signal OUT in the preparation period, and V2 represents a voltage of the output signal OUT in the output period.

With reference to FIG. 12, first, description will be given of the operations in the positive polarity mode. During the preparation period, the switches SW31, SW33, SW34 and SW36 are on while the remaining switches are off. Herein, a positive-side input voltage of the differential amplifier 30 is set at Vr and a negative-side input voltage of the differential amplifier 30 is set at V1. Therefore, the equations (3a) and (3b) are established also in the buffer circuit 3. Moreover, the data voltage Vd is applied to each of the nodes N1 and N5; therefore, each of an inter-electrode voltage of the capacitor 31 and an inter-electrode voltage of the capacitor 33 is given by an equation V1−Vd=Vr+Vo−Vd. Herein, the capacitor 31 accumulates electric charges in an amount which is “Ca” times as large as the applied voltage, and the capacitor 33 accumulates electric charges in an amount which is “Cc” times as large as the applied voltage. On the other hand, the reference voltage Vr is applied to the node N3; therefore, an inter-electrode voltage of the capacitor 32 is given by an equation V1−Vr=Vo. Herein, the capacitor 32 accumulates electric charges in an amount which is “Cb” times as large as the applied voltage.

During the output period, the switches SW32, SW35 and SW37 are on while the remaining switches are off. Herein, the positive-side input voltage of the differential amplifier 30 is set at Vr and the output voltage of the differential amplifier 30 is set at V2. Therefore, when the negative-side input voltage of the differential amplifier 30 is set at V3, the equations (3c) and (3d) are established also in the buffer circuit 3. Moreover, each of the inter-electrode voltage of the capacitor 31 and the inter-electrode voltage of the capacitor 33 equates to (V3−Vr), and the inter-electrode voltage of the capacitor 32 equates to (V3−V2).

A total amount of electric charges accumulated in the capacitors 31 to 33 does not vary between the preparation period and the output period. Therefore, the following equation (5e) is established.

Ca(Vr+Vo−Vd)+Cb·Vo+Cc(Vr+Vo−Vd)=Ca(V3−Vr)+Cb(V3−V2)+Cc(V3−Vr) (5e)

The following equation (5f) is derived from the equations (3d) and (5e).

V2=Vr+{(Ca+Cc)/Cb}×(Vd−Vr) (5f)

With reference to FIG. 13, next, description will be given of the operations in the negative polarity mode. During the preparation period, the switches SW31, SW33, SW35 and SW36 are on while the remaining switches are off. Herein, the positive-side input voltage of the differential amplifier 30 is set at Vr and the negative-side input voltage of the differential amplifier 30 is set at V1. Therefore, the equations (3a) and (3b) are established also in the negative polarity mode. Moreover, the reference voltage Vr is applied to each of the nodes N1 and N3; therefore, each of the inter-electrode voltage of the capacitor 31 and the inter-electrode voltage of the capacitor 32 is given by an equation of V1−Vr=Vo. Herein, the capacitor 31 accumulates electric charges in an amount which is “Ca” times as large as the applied voltage, and the capacitor 32 accumulates electric charges in an amount which is “Cb” times as large as the applied voltage. On the other hand, the data voltage Vd is applied to the node N5; therefore, the inter-electrode voltage of the capacitor 33 is given by an equation V1−Vd=Vr+Vo−Vd. Herein, the capacitor 33 accumulates electric charges in an amount which is “Cc” times as large as the applied voltage.

During the output period, the switches SW32, SW34 and SW37 are on while the remaining switches are off. Herein, the positive-side input voltage of the differential amplifier 30 is set at Vr and the output voltage of the differential amplifier 30 is set at V2. Therefore, when the negative-side input voltage of the differential amplifier 30 is set at V3, the equations (3c) and (3d) are established also in the negative polarity mode. Moreover, the inter-electrode voltage of the capacitor 31 equates to (V3−Vd), the inter-electrode voltage of the capacitor 32 equates to (V3−V2), and the inter-electrode voltage of the capacitor 33 equates to (V3−Vr).

A total amount of electric charges accumulated in the capacitors 31 to 33 does not vary between the preparation period and the output period. Therefore, the following equation (6e) is established.

Ca·Vo+Cb·Vo+Cc(Vr+Vo−Vd)=Ca(V3−Vd)+Cb(V3−V2)+Cc(V3−Vr) (6e)

The following equation (6f) is derived from the equations (3d) and (6e).

V2=Vr−{(Ca−Cc)/Cb}×(Vd−Vr) (6f)

It is assumed herein that (Vd−Vr) in each of the equations (5f) and (6f) is ΔV. In this case, the voltage of the output signal OUT is expressed by the following equation (5) in the positive polarity mode, and is expressed by the following equation (6) in the negative polarity mode.

V2=Vr+(Ca/Cb)×ΔV+(Cc/Cb)×ΔV (5)

V2=Vr−(Ca/Cb)×ΔV+(Cc/Cb)×ΔV (6)

As described above, the buffer circuit 3 outputs a voltage which is higher than the voltage {Vr+(Cc/Cb)×ΔV} by (Ca/Cb)×ΔV in the positive polarity mode, and outputs a voltage which is lower than the voltage {Vr+(Cc/Cb)×ΔV} by (Ca/Cb)×ΔV in the negative polarity mode. Moreover, each of the output voltages does not depend on the offset voltage Vo of the differential amplifier 30. The output voltage of the buffer circuit 3 is equal to the output voltage of the buffer circuit 2 according to the second embodiment upon reception of the voltage {Vr+(Cc/Cb)×ΔV} as the reference voltage.

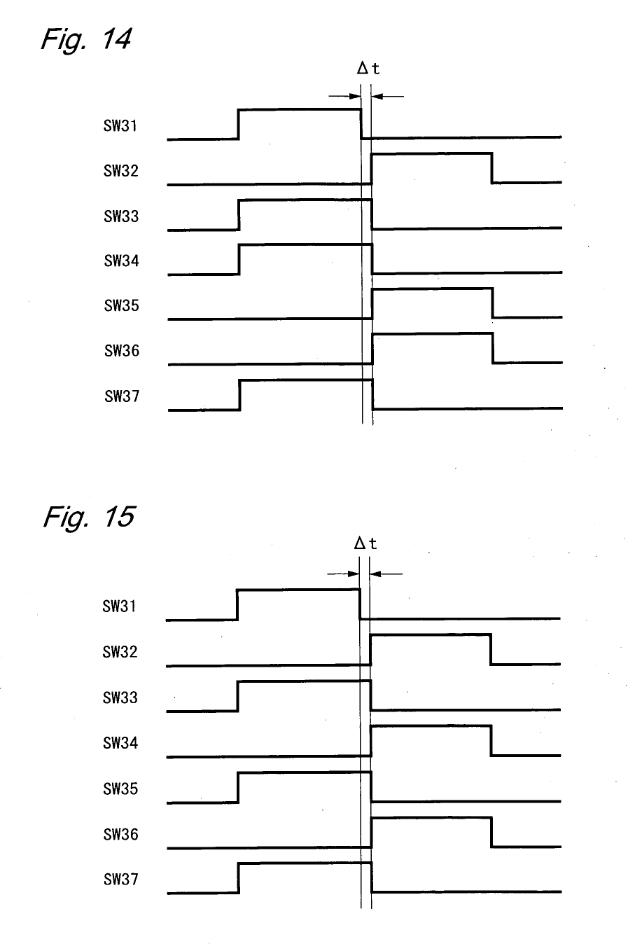

Note that the respective states of the switches SW31 to SW37 may be changed in accordance with timing charts shown in FIGS. 14 and 15. FIG. 14 is a timing chart showing a second change in state of each switch in the positive polarity mode, and FIG. 15 is a timing chart showing a second change in state of each switch in the negative polarity mode. In the timing charts shown in FIGS. 14 and 15, the switch SW36 is on during a period which is equal to the ON period of the switch SW32 and the switch SW37 is on during a period which is almost equal to the ON period of the switch SW31.

Herein, the voltage of the output signal OUT is obtained in accordance with a procedure which is equal to that in the case where the equations (5) and (6) are derived. As a result, the voltage of the output signal OUT is expressed by the following equation (7) in the positive polarity mode, and is expressed by the following equation (8) in the negative polarity mode.

V2=Vr+(Ca/Cb)×ΔV−(Cc/Cb)×ΔV (7)

V2=Vr−(Ca/Cb)×ΔV−(Cc/Cb)×ΔV (8)

In this case, the buffer circuit 3 outputs a voltage which is higher than the voltage {Vr−(Cc/Cb)×ΔV} by (Ca/Cb)×ΔV in the positive polarity mode, and outputs a voltage which is lower than the voltage {Vr−(Cc/Cb)×ΔV} by (Ca/Cb)×ΔV in the negative polarity mode. Moreover, each of the output voltages does not depend on the offset voltage Vo of the differential amplifier 30. The output voltage of the buffer circuit 3 is equal to the output voltage of the buffer circuit 2 according to the second embodiment upon reception of the voltage {Vr−(Cc/Cb)×ΔV} as the reference voltage.

As in the case of the buffer circuit 2 according to the second embodiment, accordingly, according to the buffer circuit 3 according to this embodiment, two types of gradation voltages each required for AC drive of a liquid crystal can be accurately generated with a small circuit scale. Herein, an amplitude of the output voltage can be made larger than that of the data voltage Vd, and the differential amplifier 30 having a narrow input voltage range can be used. Moreover, the reference voltage varies in an amount which is “(Cc/Cb)” times as large as a degree of change of the data voltage Vd. Accordingly, through use of the capacitors 32 and 33 each having an appropriate capacitance, the reference voltage can be corrected in accordance with the data voltage Vd and then the two types of gradation voltages each required for AC drive of the liquid crystal can be accurately generated.

As described above, according to the buffer circuit according to each embodiment of the present invention and the liquid crystal display device including the same, two types of gradation voltages each required for AC drive of a liquid crystal can be accurately generated with a small circuit scale.

### INDUSTRIAL APPLICABILITY

The buffer circuit according to the present invention has a feature capable of accurately generating two types of voltages with a small circuit scale. In a liquid crystal display device, therefore, the buffer circuit can be used for generating two types of gradation voltages each required for. AC drive of a liquid crystal. Moreover, the liquid crystal display device according to the present invention can be utilized as a display unit of various types of electronic equipments.

1. A buffer circuit for switching a level of an output voltage in accordance with an operation mode, comprising:
a differential amplifier;
a capacitor having a first terminal, and a second terminal connected to a negative-side input terminal of the differential amplifier;
a first switch switching connection/disconnection between the negative-side input terminal and an output terminal of the differential amplifier;
a second switch switching connection/disconnection between the first terminal and the output terminal of the differential amplifier;
a first voltage switch unit selecting one of a data voltage and a reference voltage to apply the selected voltage to the first terminal; and
a second voltage switch unit selecting one of the data voltage and the reference voltage to apply the selected voltage to a positive-side input terminal of the differential amplifier.

2. The buffer circuit according to claim 1, wherein
the first and second switches are on during different periods, respectively,
in the first operation mode, the first voltage switch unit selects the data voltage in the state that the first switch is on while the second voltage switch unit selects the reference voltage, and
in the second operation mode, the first voltage switch unit selects the reference voltage in the state that the first switch is on while the second voltage switch unit selects the data voltage in the state that the first switch is on and selects the reference voltage in the state that the second switch is on.

3. The buffer circuit according to claim 1, wherein
the first voltage switch unit includes:
a third switch having a first end to which the data voltage is applied, and a second end connected to the first terminal; and
a fourth switch having a first end to which the reference voltage is applied, and a second end connected to the first terminal, and
the second voltage switch unit includes:
a fifth switch having a first end to which the data voltage is applied, and a second end connected to the positive-side input terminal of the differential amplifier; and
a sixth switch having a first end to which the reference voltage is applied, and a second end connected to the positive-side input terminal of the differential amplifier.

4. A buffer circuit for switching a level of an output voltage in accordance with an operation mode, comprising:
a differential amplifier having a positive-side input terminal to which a reference voltage is applied;
a first capacitor having a first terminal, and a second terminal connected to a negative-side input terminal of the differential amplifier;
a second capacitor having a third terminal, and a fourth terminal connected to the negative-side input terminal of the differential amplifier;
a first switch switching connection/disconnection between the negative-side input terminal and an output terminal of the differential amplifier;
a second switch switching connection/disconnection between the third terminal and the output terminal of the differential amplifier;
a third switch switching application/non-application of the reference voltage to the third terminal; and
a voltage switch unit selecting one of a data voltage and the reference voltage to apply the selected voltage to the first terminal.

5. The buffer circuit according to claim 4, wherein
the first and second switches are on during different periods, respectively,
the third switch is on during a period which is substantially equal to the ON period of the first switch,
in the first operation mode, the voltage switch unit selects the data voltage in the state that the first switch is on and selects the reference voltage in the state that the second switch is on, and
in the second operation mode, the voltage switch unit selects the reference voltage in the state that the first switch is on and selects the data voltage in the state that the second switch is on.

6. The buffer circuit according to claim 4, wherein
the voltage switch unit includes:
a fourth switch having a first end to which the data voltage is applied, and a second end connected to the first terminal; and
a fifth switch having a first end to which the reference voltage is applied, and a second end connected to the first terminal.

7. The buffer circuit according to claim 4, further comprising:
a third capacitor having a fifth terminal, and a sixth terminal connected to the negative-side input terminal of the differential amplifier; and
an auxiliary voltage switch unit selecting one of the data voltage and the reference voltage to apply the selected voltage to the fifth terminal.

8. The buffer circuit according to claim 7, wherein
the auxiliary voltage switch unit selects the data voltage in a state that the first switch is on and selects the reference voltage in a state that the second switch is on.

9. The buffer circuit according to claim 7, wherein
the auxiliary voltage switch unit selects the reference voltage in a state that the first switch is on and selects the data voltage in a state that the second switch is on.

10. The buffer circuit according to claim 7, wherein
the auxiliary voltage switch unit includes:
a sixth switch having a first end to which the data voltage is applied, and a second end connected to the fifth terminal; and
a seventh switch having a first end to which the reference voltage is applied, and a second end connected to the fifth terminal.

11. A liquid crystal display device comprising the buffer circuit according to claim 1.

12. A liquid crystal display device comprising the buffer circuit according to 2.

13. A liquid crystal display device comprising the buffer circuit according to 3.

14. A liquid crystal display device comprising the buffer circuit according to 4.

15. A liquid crystal display device comprising the buffer circuit according to 5.

16. A liquid crystal display device comprising the buffer circuit according to 6.

17. A liquid crystal display device comprising the buffer circuit according to 7.

18. A liquid crystal display device comprising the buffer circuit according to 8.

19. A liquid crystal display device comprising the buffer circuit according to 9.

20. A liquid crystal display device comprising the buffer circuit according to 2.
